(19) United States
(12) Patent Application Publication
(10) Pub. No.: US 2016/0125557 A1
(43) Pub. Date: May 5, 2016

(54) System for Continuous Computation of Renewable Energy Power Production

(71) Applicant: YELOHA LTD., Tel Aviv (IL)

(72) Inventors: Amit Rosner, Tel Aviv (IL); Idan Ofrat, Tel Aviv (IL); Nathalie Hauser, Tel Aviv (IL); Omer Ramote, Tel Aviv (IL); Paolo Tedone, Tel Aviv (IL)

(21) Appl. No.: 14/893,013

(22) PCT Filed: May 21, 2014
(86) PCT No.: PCT/IL2014/050453

§ 371 Date: Nov. 20, 2015

Related U.S. Application Data
(60) Provisional application No. 61/825,555, filed on May 21, 2013.
(60) Provisional application No. 61/976,527, filed on Apr. 8, 2014.

(51) Int. Cl. G06Q 50/06; G06Q 10/06

(52) U.S. Cl. CPC G06Q 50/06; G06Q 10/06313

(57) ABSTRACT

A method for installing a renewable energy power generation system at a selected site, having a first database with a first group of installed power generating systems; a second database with a second group of power generating systems selected from the first group based on a location match to predetermined location parameters; a third database with a third group of power generating systems selected from the second group based on correlation match to predetermined correlation parameters; a fourth database storing operational data from the third group characterizing the power generating systems, and a fifth database with various types of power generating systems; a power generation system is selected from the fifth database that is capable of producing the averaged normalized potential power generation at the geographic proximity of the selected site. Finally the selected power generation system is installed at the selected site.

### FIELD OF THE INVENTION

The present invention relates to renewable energy power production systems. More particularly, the present invention relates to a system and a method for optimization of continuous renewable energy power production, and installation of power production units.

### BACKGROUND OF THE INVENTION

Use of renewable energy sources has been increasing every year in both residential and commercial domains, and in particular the use of solar energy has become common in our daily life as a source of non-polluting and affordable electric power. While in some countries wind turbines producing electric power are becoming an integral part of the scenery, it is very common now to find houses (or industrial buildings) with solar panels producing electrical power.

Prior to the installation of a photovoltaic panel array (i.e. a solar panel system), the general location and physical position (e.g. inclination angle and azimuth in respect to the direction of solar rays), and product selection (e.g. panel type and inverter type), must be cautiously selected in order to achieve maximum exposure to sunlight so that production of electrical power is optimal. With a growing number of solar systems connected to data logger devices (often transmitting measurements of the system's output to a central monitoring server) which are built-in internal parts or external devices, it is possible to deduce the expected power production of a single solar panel with known parameters.

There is therefore a need for a system that can utilize the parameters of various power generation arrays and a physical location of installation, as well as the ambient weather conditions (e.g. irradiance levels) and electric consumption at the location in order to predict potential renewable-energy power generation, in a continuous fashion over a certain time period, also prior to actually installing the array, and to determine the optimal configuration and/or location for the intended solar array.

### SUMMARY OF THE INVENTION

According to a first aspect a method for installing a renewable energy power generation system at a selected site is provided, the method comprising:

providing a first database with a first group of installed power generating systems;

defining predetermined location parameters;

tagging a second group of power generating systems selected from the first group,

wherein the selection is based on a location match of the first group to the predetermined location parameters;

providing a processing server, comprising

a second database with tags of the second group of power generating systems,

a third database with tags of a third group of power generating systems,

a fourth database configured to allow storage of operational data characterizing the power generating systems, and

a fifth database with data of various types of power generating systems;

defining predetermined correlation parameters;

tagging a third group of power generating systems selected from the second group, into the third database, wherein the selection is based on correlation match to the predetermined correlation parameters;

storing operational data from the third group into the fourth database and associating the operational data from each power generating system in the third group with the system's tag;

normalizing generated power data of each power generation system in the third group, based on operational data from the fourth database;

calculating averaged potential power generation data at the geographic proximity of the selected site, based on the normalized data;

adjusting the calculated average potential power according to the physical structure parameters at the selected site;

selecting a power generation system from the fifth database capable of producing the adjusted averaged potential power generation; and

installing the selected power generation system at the selected site,

wherein the operational data comprises generated power output and physical structure parameters of the power generation system.

In some embodiments, the processing server further comprises an electric output database with power generation efficiency values corresponding to various types of power generation systems, and wherein the calculation of the potential power generation is also based on the power generation values from the electric output database.

In some embodiments, the method further comprises providing a user terminal, having an interactive display and configured to allow transmission of information to the processing server.

In some embodiments, the method further comprises transmitting ambient conditions data for the selected site, to the processing server.

In some embodiments, the processing server is further configured to allow receiving weather information from an ambient conditions sensor located in the geographic proximity of the selected site.

In some embodiments, the processing server is further configured to allow receiving power consumption information from a power consumption meter located at the selected site.

In some embodiments, the method further comprises displaying the calculated potential power generation as a report at the user terminal.

In some embodiments, the operational data further comprises ambient temperature and operating temperature.

According to a second aspect, a method for installing a renewable energy power generation system at a selected site is provided, the method comprising:

providing input parameters, characterizing the geographic location and physical structure parameters of the selected site;

providing a processing server, comprising

a power generation system type database with data of various types of power generating systems, and

an electric output database with data of power generation efficiency values corresponding to various types of power generation systems from the power generation system type database;

transmitting ambient conditions data for the selected site, to the processing server;

calculating potential power generation at the selected for each type of potential power generation system, based on the input parameters and on power generation efficiency values from the electric output database;

adjusting the potential power generation according to the ambient conditions data, wherein changes in ambient conditions correspond to changes in potential power generation;

selecting a power generation systems from the power generation system type database capable of producing the adjusted potential power generation; and

installing the selected power generation system at the selected site.

In some embodiments, the method further comprises providing a user terminal, having an interactive display and configured to allow transmission of input parameters to the processing server.

In some embodiments, the processing server is further configured to allow receiving weather information from ambient conditions sensors located in the geographic proximity of the selected site.

In some embodiments, the processing server is further configured to allow receiving power consumption information from a power consumption meter located at the selected site.

In some embodiments, the method further comprises displaying the calculated potential power generation as a report at the user terminal.

In some embodiments, the method further comprises storing generated power in an electric power storage facility.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the specification, including definitions, will control. In addition, the materials, methods, and examples are illustrative only and not intended to be limiting.

### BRIEF DESCRIPTION OF THE DRAWINGS

Embodiments are herein described, by way of example only, with reference to the accompanying drawings. With specific reference now to the drawings in detail, it is stressed that the particulars shown are by way of example and for purposes of illustrative discussion of the preferred embodiments, and are presented in the cause of providing what is believed to be the most useful and readily understood description of the principles and conceptual aspects of the embodiments. In this regard, no attempt is made to show structural details in more detail than is necessary for a fundamental understanding of the invention, the description taken with the drawings making apparent to those skilled in the art how the several forms of the invention may be embodied in practice.

In the drawings:

FIG. 1A schematically illustrates a commercially available array of solar panels positioned on the roof of a building, according to an exemplary embodiment.

FIG. 1B schematically illustrates a partial cross-sectional side view of the building shown in FIG. 1A.

FIG. 2 schematically illustrates a system for continuous computation of solar energy production, according to an exemplary embodiment.

FIG. 3 schematically illustrates the computation system receiving data from a sensor of ambient conditions, according to an exemplary embodiment.

FIG. 4 schematically illustrates the computation system receiving data from a power consumption meter, according to an exemplary embodiment.

FIG. 5 shows an exemplary diagram comparing between power consumption and production with a solar panel array.

FIG. 6 schematically illustrates an environmental system for continuous computation of solar energy production receiving data from previously installed real solar arrays in the proximity of the user's location, according to an exemplary embodiment.

FIG. 7A schematically illustrates a solar panel array installed on a roof, according to an exemplary embodiment.

FIG. 7B schematically illustrates a solar panel array installed on a roof partially shaded, according to an exemplary embodiment.

FIG. 8 schematically illustrates the environmental system with an additional ambient conditions sensor, according to an exemplary embodiment.

FIG. 9 schematically illustrates the environmental system utilized for the domain of renewable wind energy, according to an exemplary embodiment.

### DESCRIPTION OF THE PREFERRED EMBODIMENTS

Before explaining at least one embodiment in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

For clarity, non-essential elements were omitted from some of the drawings.

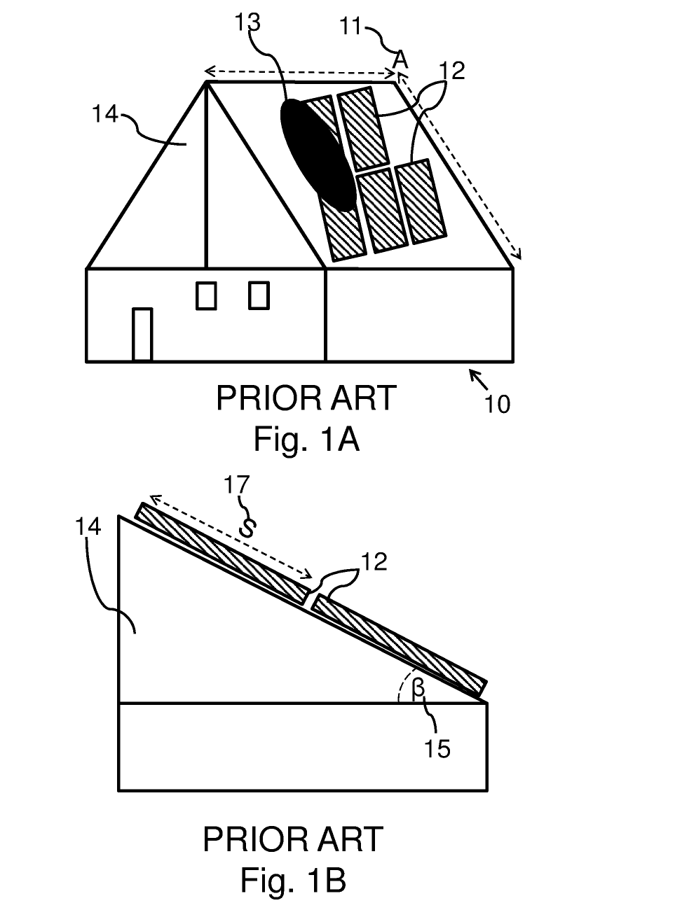

FIG. 1A schematically illustrates a commercially available array of solar panels 12 mounted onto a roof 14 of a building 10, and FIG. 1B schematically illustrates a partial cross-sectional side view of the same. The building 10 may be for instance a multistory structure or a detached home. The roof 14 has a roof area 11 (marked by “A”) that outlines the maximal area which may be covered by solar panels. Electrical power that can be produced at the solar panel array 12 having a certain efficiency may depend on multiple physical parameters, including for instance the inclination angle 15 (marked by “(3”) for the roof 14 of the building 10, the azimuth angle of the roof 14 relative to the orientation of the geographical South (not shown), and the area of each solar panel 17 (marked by “5”) covering the roof 14. In addition, the electricity production of the array is in proportion to the surface area of the solar panel array 12 and to the panel's efficiency.

It is now proposed that prior to installing a solar panel array 12, all physical parameters of the roof and of the prospective panels should be taken into account. By controlling and optimizing the installation of a solar panel array 12 to the physical parameters on the roof area 11, the generated electric power from the optimized solar panel array 12 may increase.

Furthermore, since the photovoltaic solar panel array 12 also depends on sunlight in order to produce electricity, the ambient conditions also affect the electricity production and therefore should also be taken into account, for instance the solar panels 12 being partially shaded 13 (or alternatively partially covered by snow) decreases the electrical power production.

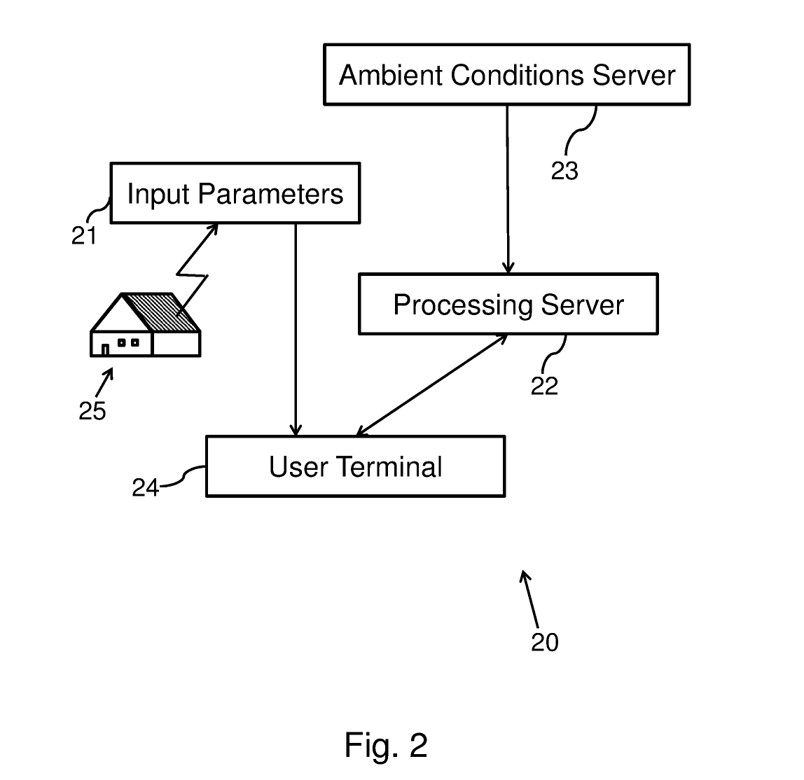

FIG. 2 schematically illustrates a monitoring system 20 embodiment for continuous computation of solar energy production. Prior to physically installing a solar panel array in a building (e.g. on the roof), a user may use the system 20 in order to create a “virtual” solar panel array (according to selection of a solar panel and of the building parameters) that continuously computes the predicted operation of such solar panel array. In this way the user may receive a detailed report indicating the expected amount of electricity that could have been produced if an actual solar panel array is installed.

The user of the system 20 may be an individual consumer (for a private or a public building) checking feasibility of installing a solar panel array, or alternatively a professional designer, installer or manufacturer of solar panels wishing to provide a consumer with a detailed report of expected electricity production. The aforementioned users can also use the system 20 to continuously compare potential production by multiple solar configurations considered for a location and determine the optimal configuration.

In a further embodiment, the users can also use the system 20 to continuously compare potential production by a certain solar array configuration in multiple locations and determine the optimal location for the eventual installation.

A user interested in information at the potential location of a solar array, may use an interactive display at a user terminal 24 for input of key attributes that may govern the potential production, describing the location and characteristics (e.g. of a roof and solar system products).

The system 20 may initially be provided with default parameter values 21 in order to initiate the computation by the system 20, at a processing server 22. In some embodiments at least some of the parameter values are replaced by input values that are deduced from input data received from sensors, for example the sensors may comprise devices for capturing aerial images of the selected rooftop or rooftop area. The system in some embodiments is capable of analyzing the aerial images to deduce the roof size and optionally other parameters. The orientation of the panels in some embodiments is independent of the orientation of the roof, so that the roof orientation parameter (deduced from the aerial image) does not affect the panel. These input parameters 21 constitute the physical parameters of the placement of the panels, which can be derived from a user's building 25, onto which the solar panel array may be installed. It should be noted that the input parameters 21 may be gathered automatically by the system 20 for a potential site at the user's building 25, or alternatively gathered manually by the user of the building 25. Additionally, some input parameters 21 may be gathered automatically by the system 20 for a potential site at the user's building 25, and some input parameters 21 may be gathered manually.

For example, the parameters for a virtual solar panel may include at least one of the following features that may govern the potential production:

Type and size of a solar panel.

Usable roof area.

Inclination angles of the roof and of the solar panel.

Azimuth of the roof relative to the direction of the geographical South.

Location of the building (in order to receive accurate ambient conditions).

Optionally, in case the user cannot provide accurate input parameters 21, the basic parameters may be retrieved merely from the location of the user's building 25. Once the user provides the location of the building 25 (e.g. by entering the address, or alternatively the accurate GPS data) then the azimuth and roof area of the building 25 may be calculated from an aerial map of the building 25. For example, the user may mark the roof area on the aerial map (not shown) to calculate expected electricity production for that area.

Additionally, in this embodiment 20 the processing server 22 requires data of the ambient conditions (e.g. temperature and irradiance level), and may receive this data from a dedicated ambient conditions server 23. The ambient conditions server 23 continuously provides information regarding the ambient conditions, as these conditions constantly change, so that a continuously updated computation may be carried out.

This computation may be carried out by providing a processing server 22 with an electric output database that may have efficiency values for electric power generation of different types and sizes of solar panels (solar panels of similar size but different types, or of different efficiencies, that can produce different amounts of electric power). Therefore, by providing the processing server 22 with accurate physical parameters 21 of the solar panel, and of the ambient conditions 23 (i.e. intensity of ambient sunlight or direct sunlight) the processing server 22 can calculate the potential electric power that may be produced if an actual solar panel is installed in the user's building 25.

Finally, the processing server 22 may create a continuous computation of a virtual solar panel array performance at the user's building 25, and transmit it to the user terminal 24 (e.g. with standard internet communication) in the form of a detailed report (for instance updated on a daily basis). It should be noted that the solar panel array may include a single solar panel or multiple solar panels with a combined power output.

Optionally, the processing server 22 may receive real-time electricity consumption information (e.g. from the electric power company or directly from a meter installed in the building) and perform a real-time comparison between electricity consumption of electric current (based on calculated input of expected power needs) and the virtual production by the prospective solar panels. By combining this comparison in the report transmitted to and displayed at the user terminal 24, the user may then observe in real-time if an installed solar panel array may provide the required electricity. In some embodiments, a comparison is carried out between the expenses of electric power usage and the expected expenses of installing a solar system over a desired amount of time (optionally the installation expenses are factored with the average upkeep expenses).

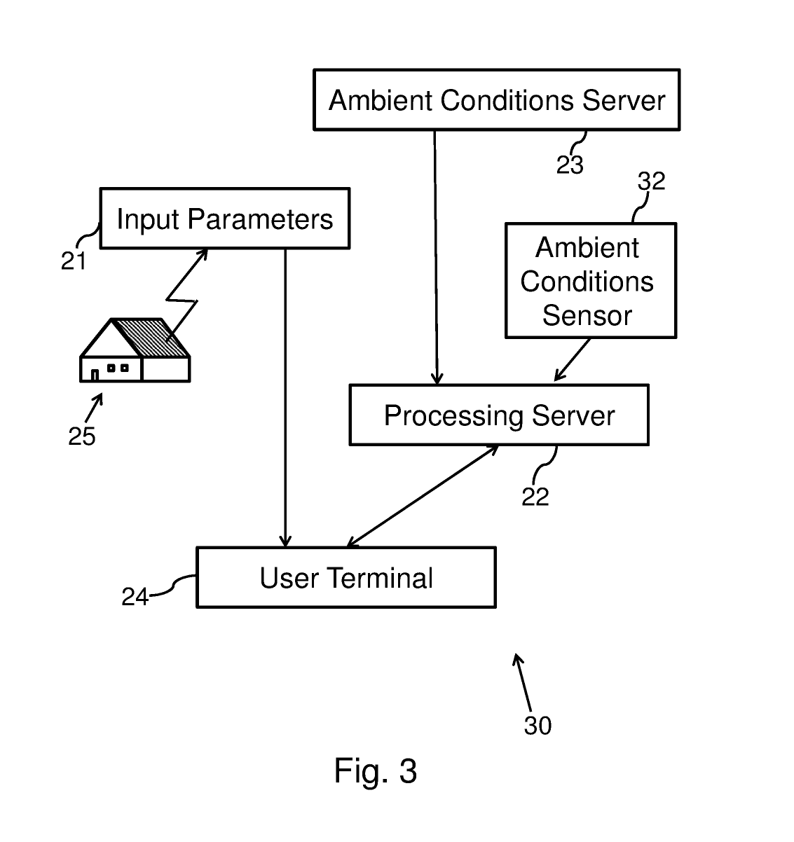

FIG. 3 schematically illustrates a further embodiment of the computation system 30, receiving data from an ambient conditions sensor 32. In this embodiment, the real weather ambient conditions (e.g. irradiance level at the roof) at or near the user's building 25 (with the virtual solar panel) are continuously measured with a physical ambient conditions sensor 32. The accurate real weather ambient conditions are then transferred to the processing server 22 (and compared with data received from the ambient conditions server 23, which may not be focused to a specific location), to be taken into account in the calculations, while the rest of the procedure is unchanged.

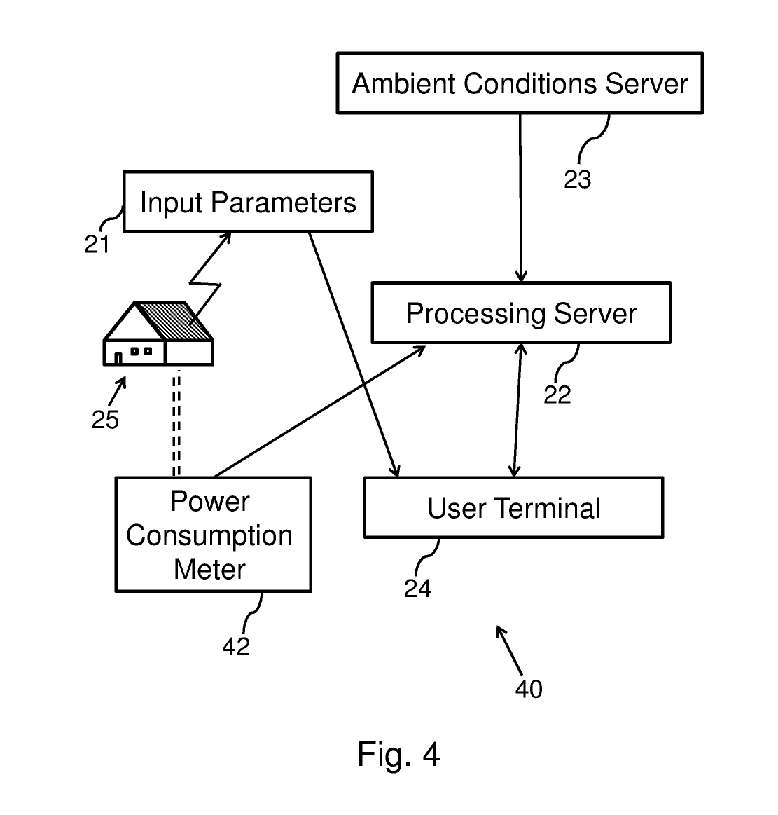

FIG. 4 schematically illustrates a further embodiment of the computation system 40, receiving data from a power consumption meter 42. In this embodiment, the actual electric power consumption of the user's building 25 (with the virtual solar panel) is continuously measured with a physical power consumption meter 42 (e.g. connected to the electrical distribution board or to a power outlet in the user's building 25) and then the measured values are directly transferred (e.g. with standard internet communication) to the processing server 22. In this way the processing server 22 may accomplish a real-time comparison, between the distribution of the actual power consumption throughout the day and the virtual power production at the user's building 25.

Optionally, the system may provide a special indication in real-time when the virtual electricity production exceeds the actual electricity consumption. Alternatively, the report transmitted to the user terminal 24 may include a total amount of virtual electricity production exceeding the actual electricity consumption.

Optionally, the system may further comprise an electric power storage facility for storing generated power that exceeds the actual power consumption.

By providing this comparison in the report transmitted to the user terminal 24, the system may then conclude what is the optimized size and/or type of a solar panel array (for instance from a system type database) best suitable to satisfy the required electric power consumption of the user's building 25. For example, the user marks a roof area with potential nominal electricity production of 10 kWh per day, and may choose to utilize only part of the roof (as recommended by the system) with panels of a specific type in order to achieve the required electricity production (e.g. of 8 kWh), and avoid excess production at certain periods of the day (e.g. during the summer) that cannot be offset by regular consumption.

Optionally, the system may receive data from both the ambient conditions sensor and the power consumption meter.

For example, given the following input parameters:

I—Ambient solar irradiance.

s—Surface of solar installation

p—Panel type

i—Inverter type

sh—Shading factor from ambient conditions server and optionally from a user's input

T—Current temperature from ambient conditions server

b, a—Tilt (inclination angle) and azimuth (orientation) angles

lat,lng—The latitude and longitude of the panel

D—Derating factors that reduce actual power production of the solar array relative to the panels' nominal capacity, such as power loss on the cabling etc.

Then the expected power production may be calculated using an equation containing all of those parameters:

Output Power=I*s*f(p)*f(i)*f(sh)*f(T)*f(a, b, lat, lng)*f(D)

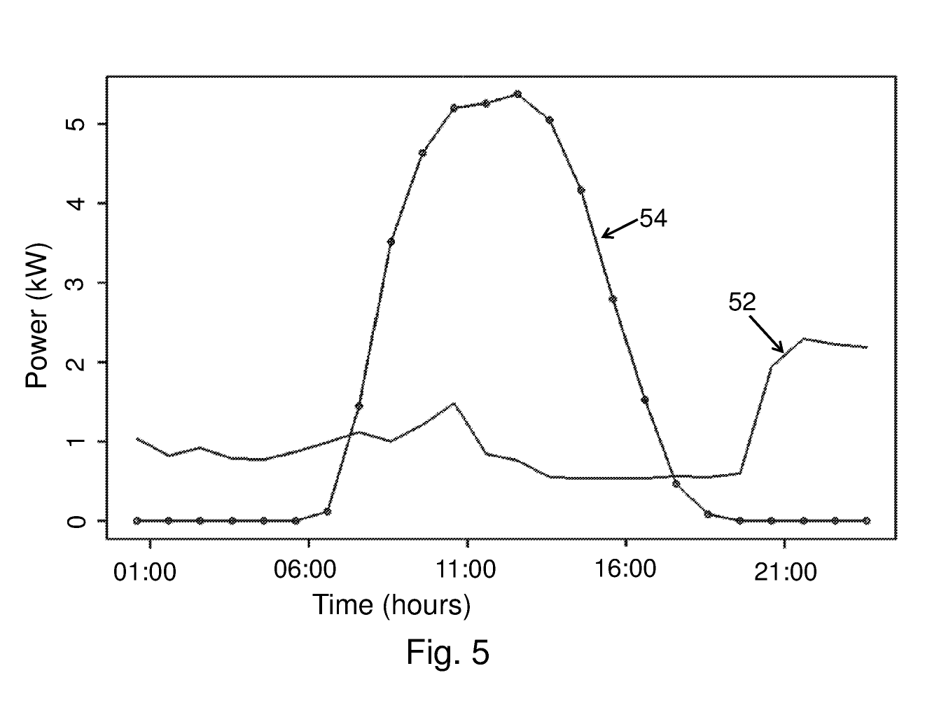

FIG. 5 shows an exemplary diagram, demonstrating the difference between actual power consumption 52 (measured in a certain household over a day), peaking during the evening, and the computed electricity production of a potential solar system 54, peaking during the afternoon (with maximum sunlight), that can be installed on the roof of that household. This diagram may be provided to each user for comparison, through the user terminal 24. Additionally, such a comparison report may also be provided as an overall sum (e.g. per day or per month), instead of hourly comparison.

Optionally, the system continuously receives information from solar power electricity production meters or solar data loggers transmitting data, based on an ongoing measurement, from previously installed real solar systems in the proximity of the user' s location. An area with a group of residential users with real systems is affected by the same ambient weather conditions and therefore may provide information on potential electricity generation in that area. This information may be then normalized for a predetermined time period per the specific parameters of the user's virtual solar panel array, and transmitted to the user terminal.

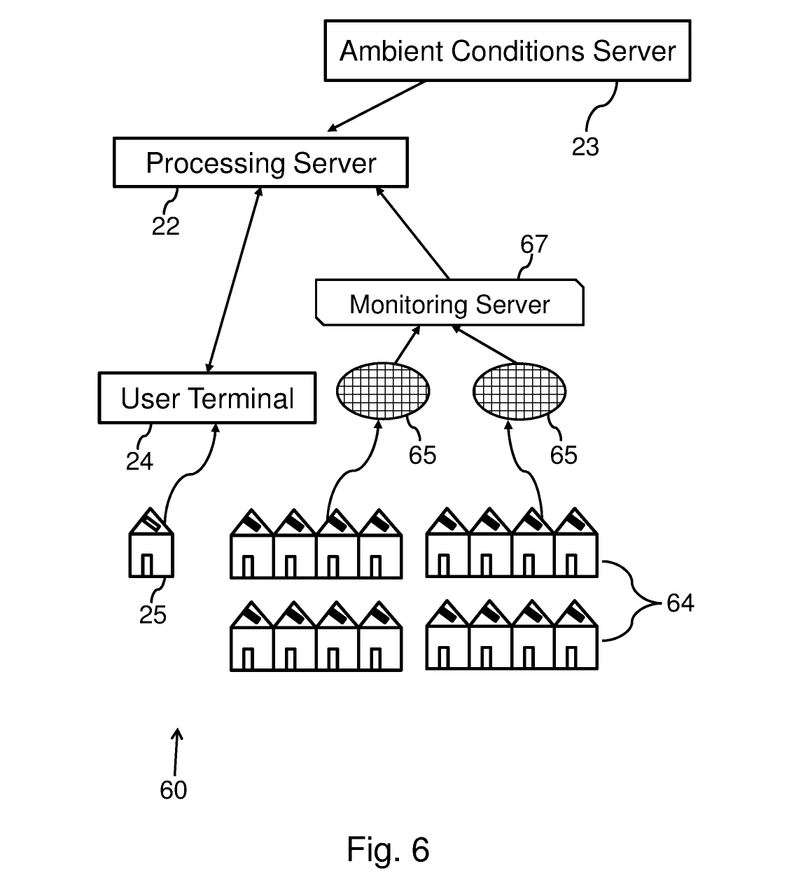

FIG. 6 schematically illustrates an environmental system 60 for continuous computation of electricity production, receiving data from previously installed real solar arrays in the proximity of the user's location. The system 60 receives information from multiple monitoring servers 67 into a single dedicated processing server 22. The multiple monitoring servers 57 continuously receive information from data loggers 65, transmitting data (e.g. with standard internet communication) from previously installed solar arrays in the proximity of the user's building 25. The calculated expected electricity production may then be normalized with the expected electricity production of the benchmark group. For example, the user may choose to utilize only part of the building with panels of a specific type in order to achieve the required electricity production, based on expected electricity production of the benchmark group.

Optionally, the system 60 receives information from data loggers 65 directly, without the need for monitoring servers 67. In a further embodiment, the system 60 receives information only from individuals and not in an automated system, without the need for data loggers 65, or monitoring servers 67.

The data loggers 65 in turn gather data from multiple users 64 having nearby solar arrays, with each data logger 65 gathering data from a single user, or alternatively from multiple users 64. The data gathered by the data loggers 65 includes the output from each of the panels of each solar array for each user 64, or the combined output from the panels of each solar system of users 64. Each data logger 65 gathers electricity generation information in a certain location (e.g. roof or ground mounted) under actual field conditions, based on an ongoing measurement of the real electricity production by real solar systems 64 installed in the proximity of a potential location of a solar array at the user's building 25.

The processing server 22 receiving the input from the user terminal 24 then finds highly correlated solar systems nearby 64 to be regarded as the benchmark group (i.e. solar systems in the same environment). It should be noted that nearby solar systems 64 may be considered as “highly correlated” if they have similar performance under the same ambient conditions. For instance, from a group of 100 nearby solar systems only 30 solar systems are chosen for the benchmark group showing correlated performance (e.g. with increase in irradiance, all of these 30 solar systems show correlated increase in power output).

Nearby benchmark groups may be found with the following steps:

Periodically adding solar systems to a database (updating the database according to changes in the distribution/types of systems), at the central dedicated server of the system 60, and preparing them for future analysis (as a standby unit for each solar system).

Finding a cluster of N “standby units” from a given location according to predetermined defined distance parameters, with highly correlated power production located in proximity to the given location.

The processing server 22 of system 60 may then commence calculation of weighted average electricity production of the benchmark group, and normalize that average per parameters (e.g. of roof) for the specific virtual site at the user's building 25. The weighted average production of the benchmark group may be calculated with the following steps:

Input N benchmark systems, with D_{1,i}−D_{N,i} total daily electricity productions for a predetermined period of past i=1 . . . m days.

From the N benchmark systems, create one “averaged” system, that takes into account the different sizes and parameters of the systems it originates from. With the result D_{avg,i} of the benchmark system for each day i=1 . . . m.

Averaging:

i. Normalize the electrical output of each system by the system's rated power (nominal) to obtain expected electricity production per 1 kW.

ii. Normalize the electrical output for each solar system's pitch and azimuth parameters, to reach the production of an optimal pitch and azimuth.

iii. Calculate the normalized cluster's averaged daily electricity production D_{avg,i}.

The normalization of the average electricity production per the specific parameters of a virtual site may be carried out by performing the following exemplary steps:

Calculating D_{v,i} averaged periodic (e.g. daily/monthly/annually) electricity production of the virtual system in the past m days by multiplying D_{avg,i} by the rated electricity of the virtual system (derived from its area).

Adjusting the electricity production according to pitch, azimuth and shading level, as defined by the user for a specific site (e.g. a roof).

Calculating aggregated virtual production in the last m days, as a sum of D_{v,i}.

Once all calculations are done, the system 60 may start an ongoing computation with the processing server 22 transmitted back to user terminal 24, with continuous updates from the data logger 65 of the nearby solar systems 64. The ongoing computation may provide the following results:

The virtual system and its benchmark groups are established.

The ongoing virtual electricity production of the virtual system is calculated and displayed on terminal 24 by applying the averaging and normalizing method of the previous steps, to each electricity production sample of the virtual system, or to a periodically aggregated electricity production (e.g. daily electricity production).

Optionally, electricity production data for the nearby solar systems 64 may be recorded and stored for long time periods in a dedicated memory. This stored information may then be transmitted to the processing server 22 in order to calculate average production of the nearby solar systems 64 over the predetermined time period (instead of real-time or daily averaging). It should be noted that the ambient conditions are not required for the system 60 in order to calculate the expected power production, as the ambient data may only provide a more accurate result.

In a preferred embodiment, the system has a first database with a first group of all installed power generating systems. By defining predetermined location parameters (e.g. particular city, or a predetermined distance from the potential site), a second group of power generating systems may be selected from the first group and stored in a second database. Each installed power generating system may be tagged based on a location match of power generating systems in the first group to the predetermined location parameters. By defining predetermined correlation parameters a third group of power generating systems may be selected from the second group and stored into a third database, where each power generating system (from the second group) may be tagged based on a correlation match of power generating systems in the second group to the predetermined correlation parameters (i.e. selecting only power generation systems that have correlated power generation performance). A fourth database may store operational data characterizing the power generating systems (such as generated power output and physical structure parameters), and a fifth database may store various types of power generating systems (e.g. different types of solar panels). By storing operational data from the third group into the fourth database and associating with the system's tag, the generated power data of each power generation system in the third group may be normalized based on operational data from the fourth database. The normalized data may then be averaged in order to deduce potential power generation at the geographic proximity of the potential site. By adjusting the calculated average potential power according to the physical structure parameters at the selected site, the specific potential power generation for the selected site is deduced. Finally a compatible power generation system (i.e. capable of producing the adjusted averaged potential power generation) may be selected from the fifth database, and installed at the potential site.

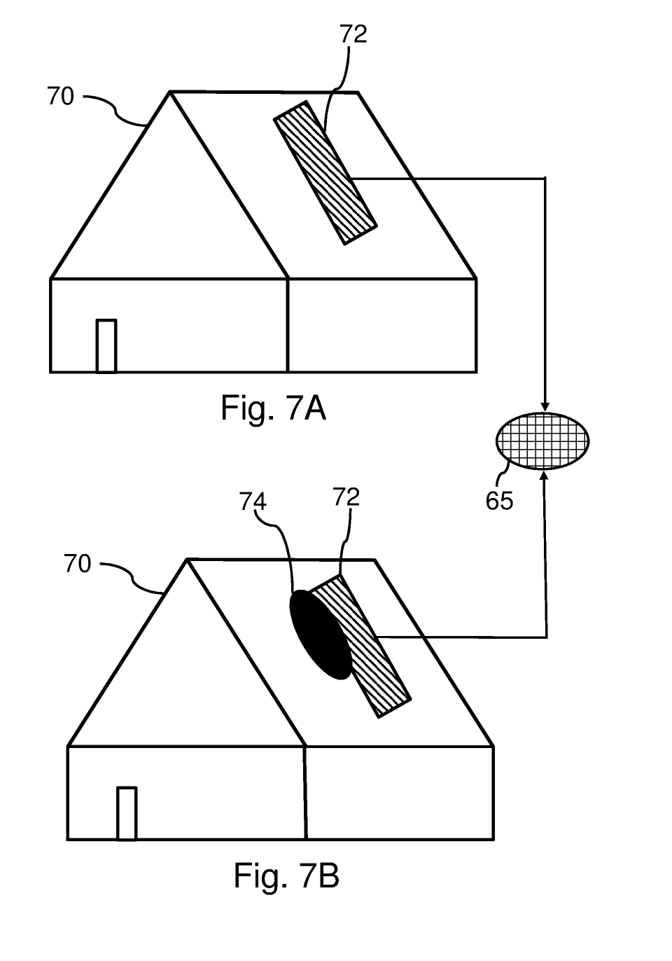

FIGS. 7A and 7B schematically illustrate a solar panel array 72 installed on a roof 70. Each solar panel array 72 is connected to the data logger 65 with continuous transmission of data. If the conditions in a solar panel 72 are changed, for example as shown in FIG. 7B with partial or full shade 74, due to temporary weather change or a constant physical obstruction affecting the entire area of several roofs 70, then the production of electricity is reduced and the weighted average production of the benchmark group must also change.

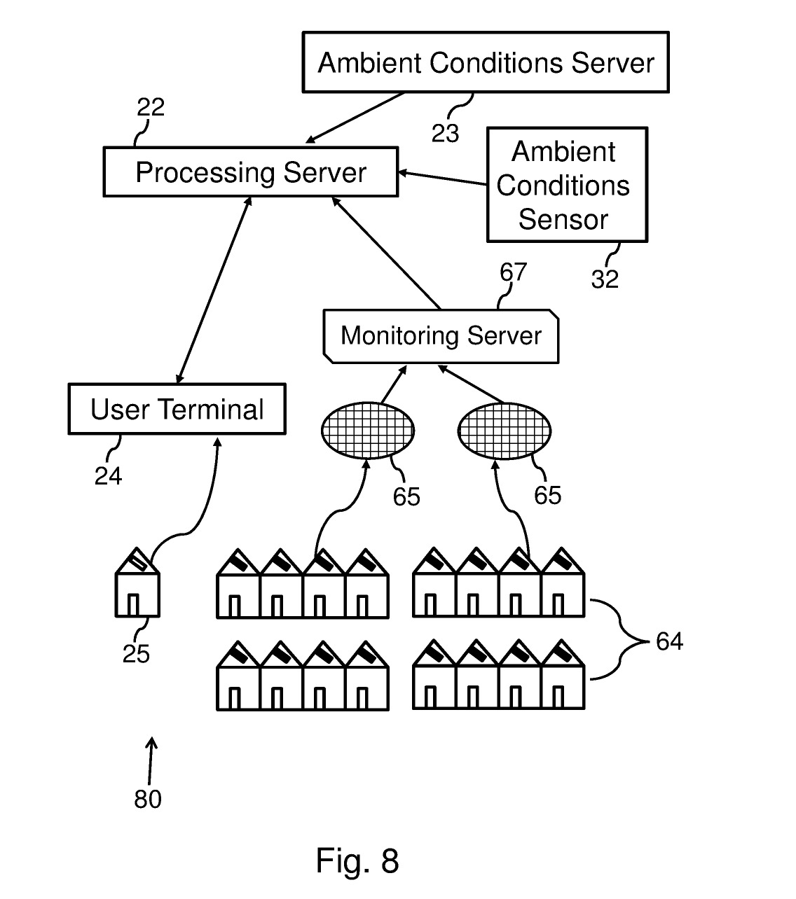

FIG. 8 schematically illustrates the environmental system 80 with an additional ambient conditions sensor 32. In this embodiment, the ambient weather conditions (e.g. clouds disturbing sunlight) at or near the potential site for a solar system at the user's building 25, are measured with a physical sensor 32 and transferred to the processing server 22 to be taken into account in the calculation of the electricity production, while the rest of the procedure is unchanged with data loggers 65 providing data for the benchmark group at a nearby site 64.

Optionally, the environmental system may receive data from both the ambient conditions sensor and the electrical power consumption meter (not shown).

In a further embodiment, the potential solar array at the user's building is intended for heating water and not for generating electricity for the electrical power grid. In this embodiment all electricity produced by the potential solar array may be utilized for heating water, instead of being converted to alternating current and then transferred to the electrical power grid. Optionally, an additional temperature sensor may be connected to such a solar array, so that if water (heated by the solar array) stored in a tank reaches a predetermined temperature then excess electricity generated by the solar array may be transferred to the electrical power grid.

It should be noted that while the above describes a system for a solar panel array, a corresponding system may be utilized for other renewable power production means (such as for wind power, hydropower, geothermic energy and others). For example in the domain of wind power, the computation will be based on similar parameters with the difference such as that instead of irradiance, the strength and direction of the wind should be taken into account.

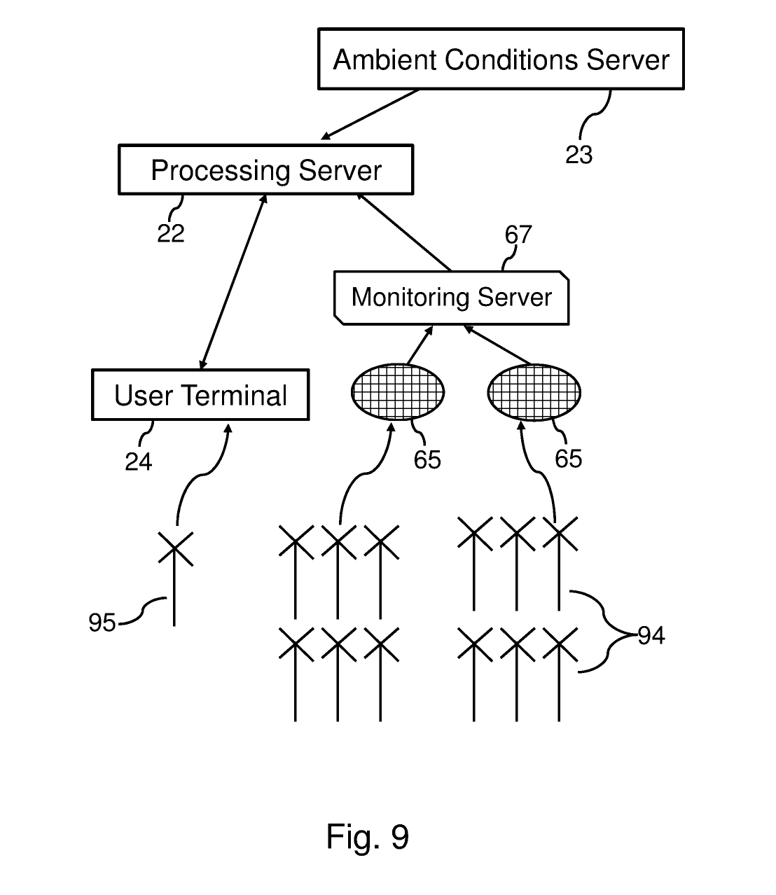

FIG. 9 shows an additional embodiment, where the environmental system is utilized for optimization of electricity production in the domain of renewable wind energy. A computation of the expected electricity production in a virtual site 95 for a wind turbine may be carried out in a similar way with information received from a benchmark group of nearby wind turbines 94. This computation may be based on similar parameters with the difference such as that instead of shade, the strength and direction of the wind should be taken into account.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub combination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

1. A method for installing a renewable energy power generation system at a selected site, the method comprising:
providing a first database with a first group of installed power generating systems; defining predetermined location parameters;
tagging a second group of power generating systems selected from the first group,
wherein the selection is based on a location match of the first group to the predetermined location parameters;
providing a processing server, comprising
a second database with tags of the second group of power generating systems,
a third database with tags of a third group of power generating systems,
a fourth database configured to allow storage of operational data characterizing the power generating systems, and
a fifth database with data of various types of power generating systems;
defining predetermined correlation parameters;
tagging a third group of power generating systems selected from the second group, into the third database, wherein the selection is based on correlation match to the predetermined correlation parameters;
storing operational data from the third group into the fourth database and associating the operational data from each power generating system in the third group with the system's tag;
normalizing generated power data of each power generation system in the third group, based on operational data from the fourth database;
calculating averaged potential power generation data at the geographic proximity of the selected site, based on the normalized data;
adjusting the calculated average potential power according to the physical structure parameters at the selected site; selecting a power generation system from the fifth database capable of producing the adjusted averaged potential power generation; and
installing the selected power generation system at the selected site, wherein the operational data comprises generated power output and physical structure parameters of the power generation system.

2. The method of claim 1, wherein the processing server further comprises an electric output database with power generation efficiency values corresponding to various types of power generation systems, and wherein the calculation of the potential power generation is also based on the power generation values from the electric output database.

3. The method of claim 1, further comprising:
providing a user terminal, having an interactive display and configured to allow transmission of information to the processing server.

4. The method of claim 1, further comprising:
transmitting ambient conditions data for the selected site, to the processing server.

5. The method of claim 4, wherein the processing server is further configured to allow receiving weather information from an ambient conditions sensor located in the geographic proximity of the selected site.

6. The method of claim 4, wherein the processing server is further configured to allow receiving power consumption information from a power consumption meter located at the selected site.

7. The method of claim 5, wherein the processing server is further configured to allow receiving power consumption information from a power consumption meter located at the selected site.

8. The method of claim 1, further comprising:
displaying the calculated potential power generation as a report at the user terminal.

9. The method of claim 1, wherein the operational data further comprises ambient temperature and operating temperature.

10. A method for installing a renewable energy power generation system at a selected site, the method comprising:
providing input parameters, characterizing the geographic location and physical structure parameters of the selected site;
providing a processing server, comprising:
a power generation system type database with data of various types of power generating systems, and
an electric output database with data of power generation efficiency values corresponding to various power generation systems from the power generation system type database;
transmitting ambient conditions data for the selected site, to the processing server;
calculating potential power generation at the selected site for each type of potential power generation system, based on the input parameters and on power generation efficiency values from the electric output database;
adjusting the potential power generation according to the ambient conditions data, wherein changes in ambient conditions correspond to changes in potential power generation;
selecting a power generation systems from the power generation system type database capable of producing the adjusted potential power generation; and
installing the selected power generation system at the selected site.

11. The method of claim 10, further comprising:
providing a user terminal, having an interactive display and configured to allow transmission of input parameters to the processing server.

12. The method of claim 10, wherein the processing server is further configured to allow receiving weather information from ambient conditions sensors located in the geographic proximity of the selected site.

13. The method of claim 10, wherein the processing server is further configured to allow receiving power consumption information from a power consumption meter located at the selected site.

14. The method of claim 12, wherein the processing server is further configured to allow receiving power consumption information from a power consumption meter located at the selected site.

15. The method of claim 11, further comprising:
displaying the calculated potential power generation as a report at the user terminal.

16. The method of claim 10, further comprising storing generated power in an electric power storage facility.
